(19) United States
(12) Patent Application Publication
(10) Pub. No.: US 2025/0358934 A1
(43) Pub. Date: Nov. 20, 2025

(54) POWER TOOL PRINTED CIRCUIT BOARD INCLUDING BUSBARS

(71) Applicant: MILWAUKEE ELECTRIC TOOL CORPORATION, Brookfield, WI (US)

(72) Inventors: Erik P. Bothe, Pewaukee, WI (US); Tingwei Wu, New Taipei City (TW); Carter H. Ypma, Milwaukee, WI (US); Zachary G. Stanke, Wausau, WI (US); Benjamin P. Leonard, Wheaton, IL (US); Max J. Santo, Chicago, IL (US)

(21) Appl. No.: 19/208,986

(22) Filed: May 15, 2025

Related U.S. Application Data
(60) Provisional application No. 63/648,371, filed on May 16, 2024.

(51) Int. Cl. H05K 1/18; B23B 45/02; H02K 11/33; H02P 27/06

(52) U.S. Cl. CPC H05K 1/181; B23B 45/02; H02K 11/33; H02P 27/06; H02K 2211/03; H05K 2201/10166; H05K 2201/10272; H05K 2201/10522; H05K 2201/1053

(57) ABSTRACT

A power tool including a motor, a power source that supplies power to the motor, and a printed circuit board (“PCB”) electrically connected to the motor and the power source. The PCB includes a switch and a busbar arranged on a surface of the PCB. The busbar electrically connects the power source to the switch for delivering an electrical current from the power source to the switch.

### RELATED APPLICATIONS

This application claims the benefit of U.S. Provisional Patent Application No. 63/648,371, filed May 16, 2024, the entire content of which is hereby incorporated by reference.

### FIELD

Embodiments described herein relate to a printed circuit board for a power tool.

### SUMMARY

A power tool typically includes a motor having a rotor and a stator. The stator includes a plurality of stator terminals (e.g., three stator terminals) which are electrically connected to a plurality of switches (e.g., field effect transistors [“FETs”], metal-oxide-semiconductor FETs [“MOSFETs”], wide bandgap semiconductor FETs, etc.). The switches are mounted on a print circuit board (“PCB”) for providing power to the motor. The switches are electrically connected to a power source via metal traces of the PCB. The switches receive power from the power source via the metal traces to be provided to the motor. However, in such instances, the metal traces of the PCB may have a thin width between the power source and the switches. Thin metal traces may provide a limited amount of power from the power source to the switches. Increasing the width, and overall size, of the metal traces will increase the size of the PCB, which may be undesirable and, in some instances, may not be feasible.

Power tools described herein include a motor, a power source that supplies power to the motor, and a printed circuit board (“PCB”) electrically connected to the motor and the power source. The PCB includes a switch and a busbar arranged on a surface of the PCB. The busbar electrically connects the power source to the switch for delivering an electrical current from the power source to the switch.

In some aspects, the PCB includes a plurality of high-side switches and a plurality of low-side switches and the switch is one of the plurality of high-side switches.

In some aspects, the PCB includes a plurality of high-side switches and a plurality of low-side switches and the switch is one of the plurality of low-side switches.

In some aspects, the busbar is a positive busbar electrically connecting the power source to the plurality of high-side switches.

In some aspects, the PCB includes a negative busbar electrically connecting the power source to the plurality of low-side switches.

In some aspects, power is supplied to the motor from the power source by controlling the switch.

In some aspects, the busbar is made of one selected from the group consisting of copper, brass, and aluminum.

In some aspects, the surface is a first surface, the switch is a first switch arranged on the first surface, the first switch having a first top surface, and the busbar is a first busbar arranged on the first top surface of the first switch, the first busbar electrically connecting the power source to the first switch.

In some aspects, the PCB includes a second surface opposite the first surface, a second switch arranged on the second surface, the second switch having a second top surface, and a second busbar arranged on the second top surface of the second switch, the second busbar electrically connecting the power source to the second switch.

Electrical devices described herein include a power tool battery pack that supplies power to a power input and a printed circuit board (“PCB”) including the power input and a power output. The PCB includes a switch and a busbar arranged on a surface of the PCB. The busbar provides power from the power input through the switch to the power output.

In some aspects, the electrical device is one selected from the group consisting of a portable power source, a lighting device, and a power tool.

In some aspects, the busbar electrically connects the power input to the switch.

In some aspects, the busbar electrically connects the switch to the power output.

In some aspects, the electrical device includes a motor electrically connected to the power output and the electrical device supplies power to the motor by controlling the switch.

In some aspects, the power input is a connector interface and the connector interface is electrically connected to the power tool battery pack and configured to receive power from the power tool battery pack.

Power tools described herein include a motor, a power source that supplies power to the motor, and a printed circuit board (“PCB”) electrically connected to the motor and the power source. The PCB includes a motor drive circuit having a plurality of high-side switches, a plurality of low-side switches, and a first busbar arranged on a surface of the PCB, the first busbar electrically connecting a positive terminal of the power source to each of the plurality of high-side switches.

In some aspects, the motor drive circuit includes a second busbar arranged on the surface of the PCB, the second busbar electrically connecting a negative terminal of the power source to each of the plurality of low-side switches.

In some aspects, the motor drive circuit includes a plurality of third busbars arranged on the surface of the PCB, the plurality of third busbars electrically connecting the plurality of high-side switches to the motor.

In some aspects, the plurality of third busbars electrically connect the plurality of low-side switches to the motor.

In some aspects, power is supplied to the motor from the power source by controlling the plurality of high-side switches and the plurality of low-side switches.

Before any embodiments are explained in detail, it is to be understood that the embodiments are not limited in its application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Other aspects of the embodiments will become apparent by consideration of the detailed description and accompanying drawings.

### BRIEF DESCRIPTION OF THE DRAWINGS

FIG. 1 illustrates a power tool, in accordance with embodiments described herein.

FIG. 2 illustrates a control system for a power tool, in accordance with embodiments described herein.

FIG. 3 illustrates a motor used in a power tool, in accordance with embodiments described herein.

FIG. 4 illustrates a printed circuit board (“PCB”) used in a power tool and including a plurality of busbars, in accordance with embodiments described herein.

FIG. 5 illustrates another embodiment of a printed circuit board (“PCB”) used in a power tool and including a plurality of busbars, in accordance with embodiments described herein.

FIG. 6 illustrates another embodiment of a printed circuit board (“PCB”) used in a power tool and including a plurality of busbars, in accordance with embodiments described herein.

FIG. 7 illustrates a motor drive circuit of a power tool, in accordance with embodiments described herein.

FIG. 8 illustrates additional embodiments of a printed circuit board (“PCB”) used in a power tool and including a plurality of busbars, in accordance with embodiments described herein.

FIG. 9 illustrates another embodiment of a printed circuit board (“PCB”) used in a power tool and including a plurality of busbars, in accordance with embodiments described herein.

FIG. 10 illustrates an isometric view of the PCB of FIG. 9, in accordance with embodiments described herein.

### DETAILED DESCRIPTION

Embodiments described herein relate to an electrical device, such as a power tool, which includes busbars and switches arranged on a print circuit board (“PCB”). The power tool includes a motor. The motor includes a rotor and a stator. The stator includes a plurality of stator terminals (e.g., three stator terminals). The PCB is electrically connected to the stator. The PCB includes a plurality of switches and a plurality of busbars. In some embodiments, the PCB includes at least six switches arranged in a switching bridge. The switches are, for example, field effect transistors (“FETs”), such as metal-oxide-semiconductor FETs (“MOSFETs”). In some embodiments, the PCB includes a plurality of busbars. A first end of each of the plurality of busbars is electrically connected to one or more of the switches. A second end of each of the plurality of the busbars is electrically connected to a power source (e.g., a battery pack) for providing power to each of the plurality of switches from the power source. In some embodiments, each busbar of the plurality of busbars is arranged between the power source and corresponding one or more switches of the plurality of switches for delivering an electrical current from the power source to the switch.

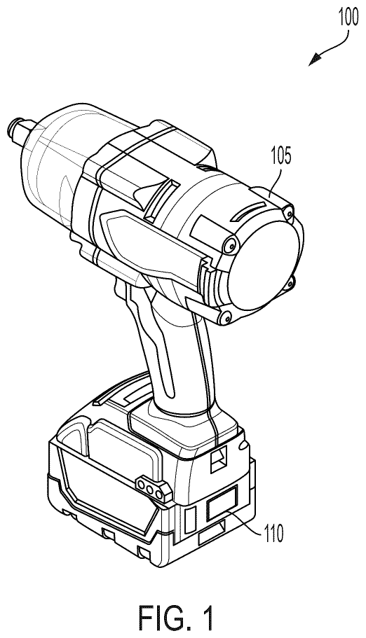

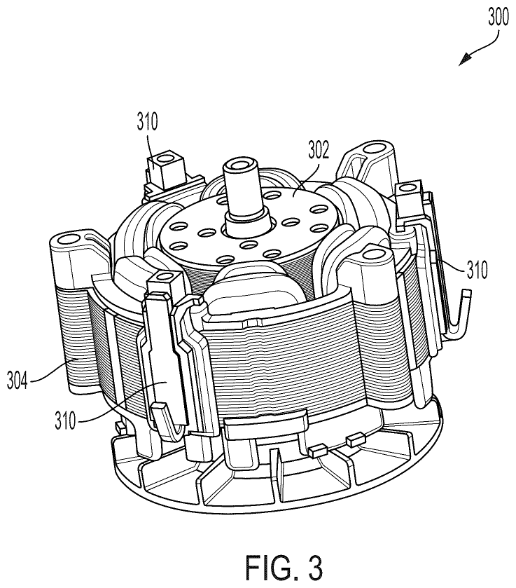

FIG. 1 illustrates a power tool 100. The power tool 100 may be, for example, an impact wrench, a drill, a ratchet, a saw, a hammer drill, an impact driver, a rotary hammer, a grinder, a blower, a trimmer, etc. The power tool 100 includes a housing or a motor housing 105 which houses a motor (see FIG. 3) within the power tool 100. The power tool 100 is configured to receive a power source 110 that provides DC power to the various components of the power tool 100, including the motor. The power source 110 may be a power tool battery pack that is rechargeable and uses, for instance, lithium-ion battery cells. In some embodiments, the power source 110 is an AC power source (e.g., 120V/60 Hz) and the power tool 100 receives power from a cord that is coupled to a standard wall outlet. In these embodiments, the received AC power may be converted to DC power by a rectifier.

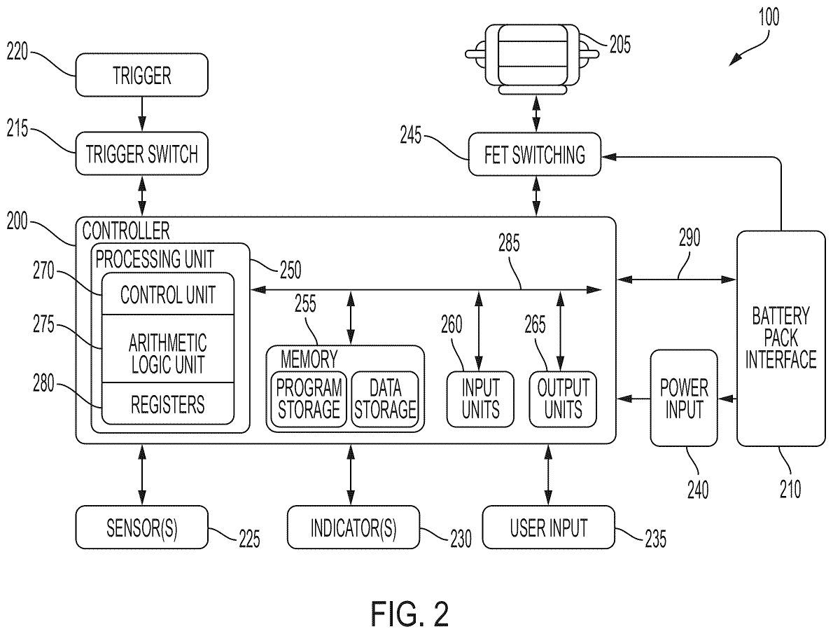

FIG. 2 illustrates a control system for the power tool 100. The control system includes a controller 200. The controller 200 is electrically and/or communicatively connected to a variety of modules or components of the power tool 100. For example, the illustrated controller 200 is electrically connected to a motor 205, a battery pack interface 210, a trigger switch 215 (connected to a trigger 220), one or more sensors or sensing circuits 225, one or more indicators 230, a user input module 235, a power input module 240, and a FET switching module 245 (e.g., including a plurality of switching FETs). The controller 200 includes combinations of hardware and software that are operable to, among other things, control the operation of the power tool 100, monitor the operation of the power tool 100, activate the one or more indicators 230 (e.g., an LED), etc.

The controller 200 includes a plurality of electrical and electronic components that provide power, operational control, and protection to the components and modules within the controller 200 and/or the power tool 100. For example, the controller 200 includes, among other things, a processing unit 250 (e.g., a microprocessor, a microcontroller, an electronic processor, an electronic controller, or another suitable programmable device), a memory 255, input units 260, and output units 265. The processing unit 250 includes, among other things, a control unit 270, an ALU 275, and a plurality of registers 280 (shown as a group of registers in FIG. 2), and is implemented using a known computer architecture (e.g., a modified Harvard architecture, a von Neumann architecture, etc.). The processing unit 250, the memory 255, the input units 260, and the output units 265, as well as the various modules or circuits connected to the controller 200 are connected by one or more control and/or data buses (e.g., common bus 285). The control and/or data buses are shown generally in FIG. 2 for illustrative purposes.

The memory 255 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 250 is connected to the memory 255 and executes software instructions that are capable of being stored in a RAM of the memory 255 (e.g., during execution), a ROM of the memory 255 (e.g., on a generally permanent basis), or another non-transitory computer readable medium such as another memory or a disc. Software included in the implementation of the power tool 100 can be stored in the memory 255 of the controller 200. The software includes, for example, firmware, one or more applications, program data, filters, rules, one or more program modules, and other executable instructions. The controller 200 is configured to retrieve from the memory 255 and execute, among other things, instructions related to the control processes and methods described herein. In other constructions, the controller 200 includes additional, fewer, or different components.

The battery pack interface 210 includes a combination of mechanical components (e.g., rails, grooves, latches, etc.) and electrical components (e.g., one or more terminals) configured to and operable for interfacing (e.g., mechanically, electrically, and communicatively connecting) the power tool 100 with a battery pack. For example, power provided by the battery pack 110 to the power tool 100 is provided through the battery pack interface 210 to the power input module 240. The power input module 240 includes combinations of active and passive components to regulate or control the power received from the battery pack 110 prior to power being provided to the controller 200. The battery pack interface 210 also supplies power to the FET switching module 245 to be switched by the switching FETs to selectively provide power to the motor 205. The battery pack interface 210 also includes, for example, a communication line 290 for provided a communication line or link between the controller 200 and the battery pack 110.

The indicators 230 include, for example, one or more light-emitting diodes (“LEDs”). The indicators 230 can be configured to display conditions of, or information associated with, the power tool 100. For example, the indicators 230 are configured to indicate measured electrical characteristics of the power tool 100, the status of the device, etc. The user input module 235 is operably coupled to the controller 200 to, for example, select a forward mode of operation or a reverse mode of operation, a torque and/or speed setting for the power tool 100 (e.g., using torque and/or speed switches), etc. In some embodiments, the user input module 235 includes a combination of digital and analog input or output devices required to achieve a desired level of control for the power tool 100, such as one or more knobs, one or more dials, one or more switches, one or more buttons, etc.

The sensors 225 include one or more current sensors, one or more speed sensors, one or more Hall-effect sensors, one or more temperature sensors, etc. The controller 200 calculates or includes, within memory 255, predetermined operational threshold values and limits for operation of the power tool 100. For example, when a potential thermal failure (e.g., of a FET, the motor 205, etc.) is detected or predicted by the controller 200, power to the motor 205 can be limited or interrupted until the potential for thermal failure is reduced.

FIG. 3 illustrates an embodiment of a motor 300, which may be located in the motor housing 105 of the power tool 100. In the example illustrated, the motor 300 is a three-phase brushless direct current (BLDC) motor. In other examples, the motor 300 may include a BLDC motor with a different number of phases, a DC motor, an AC motor, or the like that is controlled by the controller 200 using a switching arrangement (e.g., one or more FETs). The motor 300 includes a rotor 302 and a stator 304. The stator 304 is the stationary part of the motor 300 and includes a plurality of attached stator terminals 310. The stator terminals 310 may be in connection with a plurality of switches, such as Field Effect Transistors (FETs) or Metal-Oxide Semiconductor Field Effect Transistors (MOSFETs), on a PCB in the power tool 100 for providing control of the power to the motor 300.

Although described herein with respect to the power tool 100, the controller 200 and printed circuit boards (“PCBs”) described herein may be implemented in alternative embodiments other than the power tool 100. For example, the controller 200 and PCBs described herein are implemented in a portable power source. The portable power source is configured to receive the power source 110 and distribute power to external devices using the FET switching module 245. In other embodiments, the controller 200 and PCBs described herein are implemented in a lighting device (e.g., a portable light). The lighting device is configured to receive the power source 110 and includes the FET switching module 245 configured as a light-emitting diode (“LED”) driver. The lighting device controls the LED driver to control light emitted by the lighting device via power received from the power source 110. In other embodiments, the controller 200 and PCBs described herein are implemented in any suitable battery powered worksite equipment.

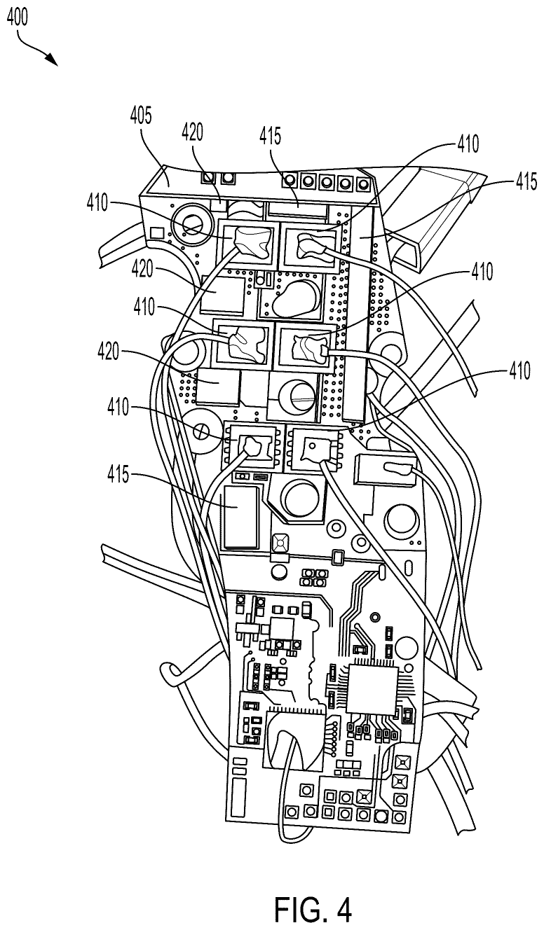

FIG. 4 illustrates a printed circuit board (“PCB”) 400 used in the power tool 100. In some embodiments, the PCB 400 includes the controller 200, the FET switching module 245, and components thereof with respect to the control system illustrated in FIG. 2. The PCB 400 includes a surface (e.g., a first surface) 405. As illustrated in the embodiment of FIG. 4, electrical and electronic components of the PCB 400 are mounted to or arranged on the surface 405 of the PCB 400. The surface 405 may be a conductive layer that provides an electrical connection between the PCB 400 and components thereof. It should be understood that the PCB 400 also includes a second surface located opposite the surface 405. In some instances, some or all of the electrical and electronic components of the PCB 400 are mounted to or arranged on the second surface. The PCB 400 also includes metal traces that electrically connect the components of the PCB 400.

The PCB 400 is electrically connected to the power source 110 and the motor 300. For example, the PCB 400 receives operational power from the power source 110 and selectively controls operational power supplied to the motor 300. The PCB 400 also includes a plurality of switches 410 (e.g., FETs of the FET switching module 245) and a plurality of busbars 415. Each switch of the plurality of switches 410 is mounted on the surface 405 of the PCB 400. Each switch of the plurality of switches 410 may be provided as a separate package, for example, as a separate integrated circuit on the PCB 400. Terminals of each of the separate plurality of switches 410 are mounted to the PCB 400, for example, using soldering. Similarly, each busbar of the plurality of busbars 415 is mounted on the surface 405 of the PCB 400. The plurality of busbars 415 are therefore separate from any conductive tracings or stampings of the PCB 400. In some instances, each busbar of the plurality of busbars 415 is arranged on the surface 405 relative to corresponding one or more switches of the plurality of switches 410. By positioning each busbar of the plurality of busbars 415 on the PCB 400 between the power source 110 and corresponding one or more switches of the plurality of switches 410, a more robust electrical connection between the power source 110 and the plurality of switches 410 is achieved.

Referring to FIG. 2, the battery pack interface 210 may include a terminal block to form an electrical and communicative connection with the battery pack 110. The terminal block includes, for example, a positive terminal, a negative terminal, and one or more communication terminals. Referring to FIG. 4, in some examples, the terminal block may be mounted directly to the PCB 400. In some examples, a connector interface including pins and corresponding pin receptacles may be used to connect the terminal block to the PCB 400. In other examples, wires may be routed from the terminal block and soldered to the PCB 400 to connect the terminal block to the PCB 400. When the terminal block is connected to the PCB, the positive terminal and the negative terminal are electrically connected to the plurality of switches 410 using the plurality of busbars 415. The one or more communication terminals may be connected to a microcontroller unit (MCU) or other similar unit that implements the controller 200 and/or the processing unit 250 via conductive traces on the PCB 400 to form the communication line 290. In some embodiments, the PCB 400 is connected to the motor 205 using motor busbars 420. Similar to the plurality of busbars 415, the motor busbars 420 are separate from any conductive tracings or stampings of the PCB 400. In some instances, each motor busbar 420 is arranged on the surface 405 relative to corresponding one or more switches of the plurality of switches 410. By positioning each motor busbar 420 on the PCB 400 between the motor 200 and corresponding one or more switches of the plurality of switches 410, a more robust electrical connection between the motor and the plurality of switches 410 is achieved. In some examples, the motor busbars 420 are embedded within the PCB 400 and routed to the motor coils. In other examples, the PCB 400 is connected to the motor 205 using wires that are soldered to the PCB 400 and connected to the motor coils.

In some embodiments, a first end of each busbar of the plurality of busbars 415 is physically and electrically connected to corresponding one or more switches of the plurality of switches 410. In other words, a first end of a busbar is electrically connected to one or more switches. For example, the first end of each busbar of the plurality of busbars 415 is soldered to a source terminal of corresponding one or more switches of the plurality of switches 410. In other embodiments, the first end of each busbar of the plurality of busbars 415 is soldered to a drain terminal of corresponding one or more switches of the plurality of switches 410. A second end of each busbar of the plurality of busbars 415 is physically and electrically connected to the power source 110. Each busbar of the plurality of busbars 415 may therefore be arranged between and electrically connects the power source 110 to the corresponding one or more switches of the plurality of switches 410. In other words, a busbar of the plurality of busbars 415 is arranged between the power source 110 and one or more switches of the plurality of switches 410 for delivering power (e.g., via an electrical current) from the power source 110 to the switch of the plurality of switches 410.

In some embodiments, the controller 200 selectively controls each switch of the plurality of switches 410 to supply power to the motor 300 from the power source 110. Each busbar of the plurality of busbars 415 is configured to increase an amount of the electrical current that can be safely and efficiently delivered to the motor 300 via the plurality of switches 410. For example, each busbar of the plurality of busbars 415 receives electrical current from the power source 110 and distributes the electrical current to corresponding one or more switches of the plurality of switches 410. Based on a material composition and a cross-sectional area of each of the plurality of busbars 415, each of the plurality of busbars 415 may receive and distribute a greater amount of electrical current from the power source 110 than traditional metal traces of a PCB. By increasing the cross-sectional area of each of the plurality of busbars 415, each of the plurality of busbars 415 distributes a greater amount of heat via conduction than traditional metal traces or stamping of a PCB. In other words, the greater the cross-sectional area of each of the plurality of busbars 415, the greater the amount of heat that can be transferred via conduction through a surrounding environment to increase a rate of heat transfer.

In some embodiments, the material composition of each busbar of the plurality of busbars 415 is one selected from the group consisting of copper, brass, and aluminum. In other words, each busbar of the plurality of busbars 415 is made of one selected from the group consisting of copper, brass, and aluminum. In other embodiments, each busbar of the plurality of busbars 415 may be composed of any other suitable electrically conductive material. It should be understood that different material compositions have different electrical resistivities that affect an amount of electrical current flowing through each busbar of the plurality of busbars 415. For example, brass typically has a greater electrical resistivity than aluminum and copper. Additionally, aluminum typically has a greater electrical resistivity than copper. As such, in busbars with equal cross-sectional areas, a busbar composed of copper allows a greater amount of electrical current to flow through the busbar than aluminum or brass. Additionally, the plurality of busbars 415 allows a greater amount of electrical current to flow through each busbar than traditional metal traces or stamping of a PCB without overheating. In some embodiments, the plurality of busbars 415 may have an outermost layer composed of a material distinct from the remainder the busbar 415. The outermost layer may be selected from the group consisting of tin, nickel, chromium, and gold, and is configured to protect the busbar 415 from oxidation and wear. The outermost layer of the busbar 415 may be applied through an electroplating procedure.

Furthermore, each busbar of the plurality of busbars 415 has a cross-sectional area. In some embodiments, the cross-sectional area of each busbar of the plurality of busbars 415 is equal to a thickness of the busbar multiplied by a width of the busbar. In some embodiments, each busbar of the plurality of busbars 415 has a different cross-sectional area. In other embodiments, each busbar of the plurality of busbars 415 has the same cross-sectional area. In some embodiments, the cross-sectional area of each busbar of the plurality of busbars 415 determines an amount of the electrical current delivered to corresponding one or more switches of the plurality of switches 410 from the power source 110. In some embodiments, the cross-sectional area of each busbar of the plurality of busbars 415 is within a range of 0.00155 square inches (sq in) to 0.5 sq in (e.g., 1 sq millimeters (mm) to 322.58 sq mm). In other embodiments, the cross-sectional area of a busbar of the plurality of busbars 415 is greater than 0.5 sq in.

As the cross-sectional area of a busbar of the plurality of busbars 415 increases, a greater amount of electrical current is delivered to corresponding one or more switches of the plurality of switches 410 since the resistance decreases as the surface area increases. Comparatively, metal traces of the PCB 400 have a smaller cross-sectional area than each busbar of the plurality of busbars 415. As such, each busbar of the plurality of busbars 415 delivers a greater amount of electrical current from the power source 110 to corresponding one or more switches of the plurality of switches 410 than metal traces of the PCB 400 alone. As the controller 200 selectively controls the plurality of switches 410 to supply power to the motor 300, the greater amount of electrical current is supplied to the motor 300 through the plurality of switches 410.

In some embodiments, each busbar of the plurality of busbars 415 includes a positive busbar and a negative busbar. In such embodiments, the positive busbar is arranged between a positive terminal of the power source 110 and corresponding one or more switches of the plurality of switches 410. The negative busbar is arranged between a negative terminal of the power source 110 and the corresponding one or more switches of the plurality of switches 410. In some embodiments, the plurality of switches 410 are arranged towards a middle of the PCB 400 and the plurality of busbars 415 are provided on an outer side of the PCB 400 in relation to the plurality of switches 410.

In traditional PCBs, metal traces and stamping techniques make manufacturing and assembly of PCBs easier and faster. Busbars are typically bulky and add steps in an assembly process to mount the busbars to PCBs. Additionally, busbars carry electrical current outside of an insulating later of the PCB, which may have undesired effects on other electrical components of the PCB. However, by careful planning of PCB design and including busbars with respect to corresponding switches, current carrying capacity of electrical circuits of a PCB can be increased without significantly increasing size of electrical components of the PCB.

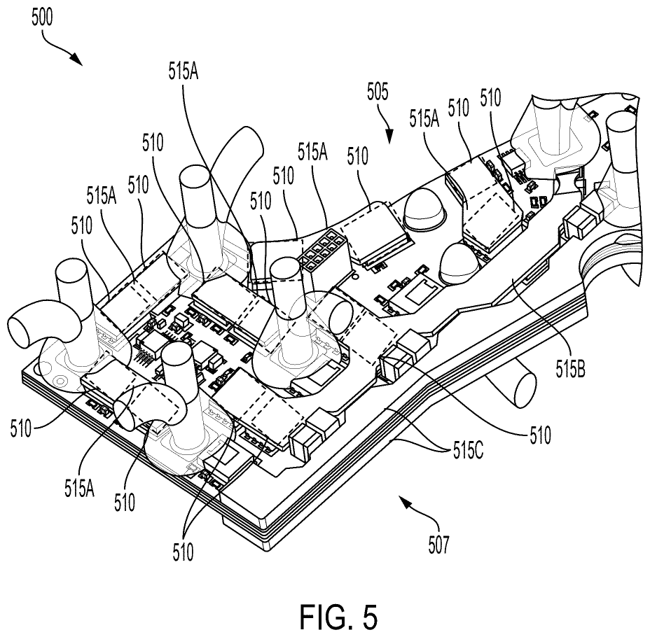

FIG. 5 illustrates another printed circuit board (“PCB”) 500, with like parts to PCB 400. The illustrated embodiment in FIG. 5 having like reference numbers in the range of 500 to 599, and the differences are explained below. The PCB 500 is electrically connected to the power source 110, the motor 300, and includes the controller 200. Additionally, the PCB 500 defines a first surface 505 and a second surface 507 opposing the first surface 505. The PCB 500 includes a plurality of switches 510 positioned on the first surface 505 and a plurality of busbars 515.

As shown in FIG. 5, 12 switches 510 (6 high-side switches and 6 low-side switches) are arranged across the first surface 505 of the PCB 500. In other embodiments, the PCB 500 may include 6 switches 510, 12 switches 510, 18 switches 510, or the like. In further embodiments, the switches 510 may be arranged solely on the second surface 507 or on the second surface 507 as well as the first surface 505. The switches 510 are provided as a separate package (i.e., an integrated circuit) and include a plurality of pins. The plurality of pins connects the switch 510 to the power source 110, the controller 200, the motor 300, or other components of the PCB 500. A first one or more of the plurality of pins contact the first surface 505 and are surface mount soldered to a plurality of traces on the first surface 505 to form an electrical and mechanical connection. The plurality of traces connects the one or more of the plurality of pins to the controller 200 or other components soldered to the PCB 500. A second one or more of the plurality of pins may extend toward and contact the busbar 515, which is positioned above the switch 510. In other embodiments, the busbar 515 may be located on the same plane as the switch 510. The second one or more of the plurality of pins may be surface mount soldered to the busbar 515 to form an electrical connection. In some examples, the second one or more of the plurality of pins may be soldered to the PCB 500 and a separate electrical connection may be provided from the PCB 500 to the busbars 515, for example, through metal traces. The electrical connection formed connects the switches 510 to the power source 110 or the motor 300. In other embodiments, the first and second pins may through-hole soldered to the PCB 500 or the bus bar 515, and the switch 510 may include an additional mechanical fastener to form a mechanical connection to the PCB 500 in addition to soldering.

As shown in FIG. 5, each busbar 515 may be positioned either in direct contact with the first and second surface 505, 507 or are offset from the first and second surface 505, 507 and in contact with a top surface of one or more switches 510. Also as shown in FIG. 5, the plurality of busbars 515 include busbars 515 of different shapes and sizes, and every busbar 515 may not extend beyond the bounds of the PCB 500. The busbars 515 facilitate an electrical connection between one of the switches 510 and the power source 110, the motor 300, or one or more of the remaining switches 510. In the illustrated embodiment, the plurality of busbars 515 includes five first busbars 515A coupling two switches 510, one second busbar 515B coupling to four switches 510 to the power supply 110, and two third busbars 515C not connected to any switches 510. In other embodiments, the number of busbars 515 may be larger or fewer than eight and the number of connections formed by each busbar 515 may increase or decrease. In some embodiments, the busbars 515 may be coupled to a heatsink or may include a plurality of fins to disperse heat away from the busbars 515.

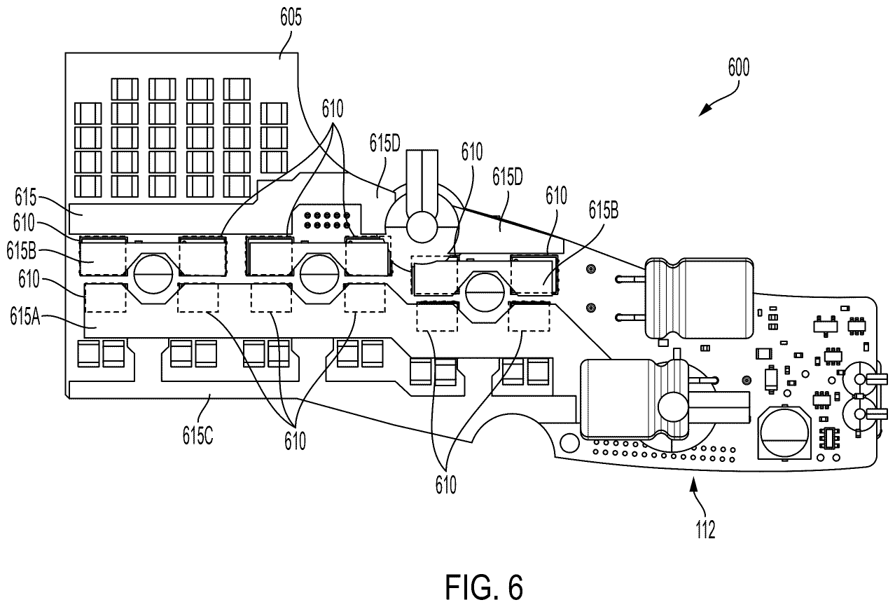

FIG. 6 illustrates another printed circuit board (“PCB”) 600, with like parts to PCBs 400 and 500. The illustrated embodiment in FIG. 6 having like reference numbers in the range of 600 to 699, and the differences are explained below. The PCB 600 is electrically connected to the power source 110 through a connector interface 112, the motor 300, and includes the controller 200. Additionally, the PCB 600 defines a first surface 605 and a second surface (not shown) opposing the first surface 605. The PCB 600 includes a plurality of switches 610 positioned on the first surface 605 and a plurality of busbars 615.

As shown in FIG. 6, 12 switches 610 (6 high-side switches and 6 low-side switches) are arranged across the first surface 605 of the PCB 600. In other embodiments, the PCB 600 may include 6 switches 610, 12 switches 610, 18 switches 610, or the like. In further embodiments, the switches 610 may be arranged solely on the second surface or on the second surface as well as the first surface 605. Like the switch 510, the switches 610 are provided as a separate package (i.e., integrated circuit) and include a plurality of pins, which electrically connect the switches 610 to the power source 110, the controller 200, the motor 300, or other components of the PCB 600. The electrical connection of the switches 610 may be formed similarly as described above with respect to FIG. 5.

As shown in FIG. 6, each busbar 615 is positioned on the first surface 605 and may be in direct contact with the first surface 605 or offset from the first surface 605 and in contact with a top surface of one or more switches 610. In other embodiments, the busbars 615 may be positioned on solely on the second surface or on both the second surface and the first surface 605. In further embodiments, the busbar 615 may be in the same plane as the switches 610. Like the busbars 515, the plurality of busbars 615 may have different shapes and sizes and every busbar 615 may not extend beyond the bounds of the PCB 600. As shown in FIG. 6, the plurality of busbars 615 includes a first busbar 615A connected to six switches 610 and to the power source 110, three second busbars 615B connected to two switches 610, a third busbar 615C connected to the first busbar 615A, and two fourth busbars 615D connected to the three second busbars 615B. The third busbar 615C is connected to the first busbar 615A to increase the cross-sectional area and allow the first busbar 615A to receive a larger current. In other embodiments, the number of busbars 615 may be larger or fewer seven total and the number of connections formed by each busbar 615 may increase or decrease.

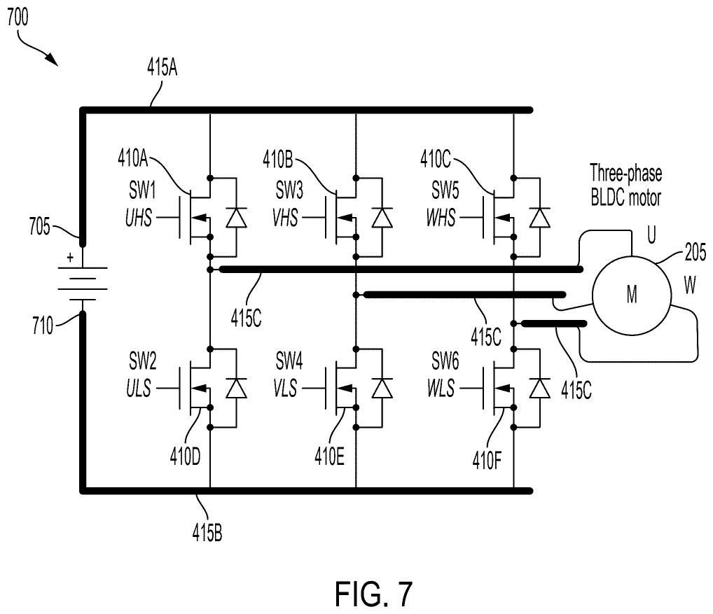

FIG. 7 illustrates an example embodiment of a motor drive circuit 700 including the plurality of switches 410 and the plurality of busbars. The motor drive circuit 700 is also compatible with the PCBs 500, 600 and the corresponding switches 510, 610 and the corresponding busbars 515, 615. The motor drive circuit 700 is provided for an example of a three-phase brushless motor 205 but can be adapted for other types of motors with different numbers of phases as discussed above. The motor drive circuit 700 includes three high-side switches 410A, 410B, 410C connected between a positive terminal 705 and the motor 205. In other embodiments, the motor drive circuit 700 may include three groups of high-side switches, where each group comprises one or more high-side switches arranged in series. The number of high side switches per group may be equivalent to the total number of high-side switches divided by the number of phases of the motor. The motor drive circuit 500 includes three low-side switches 410D, 410E, 410F connected between a negative terminal 710 and the motor 205. In other embodiments, the motor drive circuit 700 may include three groups of low-side switches, where each group comprises one or more low-side switches arranged in series. The number of low side switches per group may be equivalent to the total number of low-side switches divided by the number of phases of the motor. A positive busbar 415A is used to electrically connect the positive terminal 705 to each of the three high-side switches 410A, 410B, and 410C. A negative busbar 415B is used to electrically connect the negative terminal 710 to each of the three low-side switches 410D, 410E, 410F. A plurality of motor busbars 415C are used to connect the high-side switches 410A, 410B, and 410C and the low side switches 410D, 410E, 410F to the motor 205.

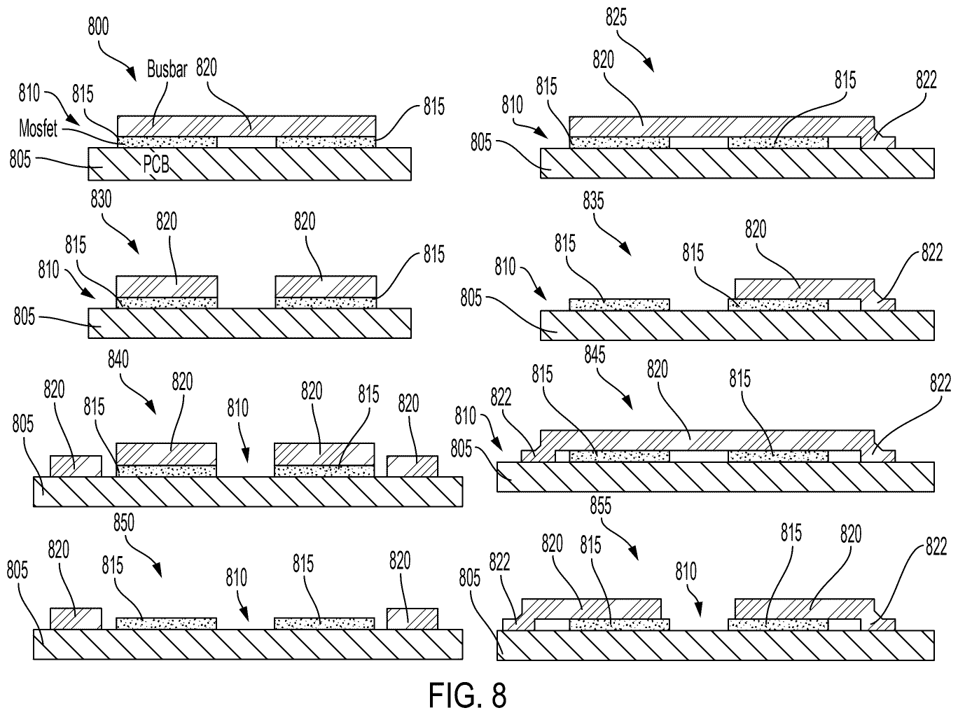

FIG. 8 illustrates additional embodiments of a printed circuit board (“PCB”) 805. The illustrated embodiments of FIG. 8 include like parts to PCBs 400, 500, and 600. The illustrated embodiments in FIG. 8 having like reference numbers in the range of 800 to 899, and the differences are explained below. The illustrated embodiments of FIG. 8 are each electrically connected to the power source 110, the motor 300, and include the controller 200. Additionally, the PCB 805 defines a first surface 810. In some embodiments, the PCB 805 defines a second surface opposing the first surface 810. In each additional embodiment illustrated in FIG. 8, the PCB 805 includes a plurality of switches 815 positioned on the first surface 810 and a plurality of busbars 820. In some embodiments, the plurality of switches 815 may be arranged solely on the second surface or on the second surface as well as the first surface 810.

As shown in FIG. 8, an embodiment 800 includes the PCB 805 having the first surface 810. The plurality of switches 815 are arranged on the first surface 810. In the embodiment 800, the plurality of busbars 820 is a single busbar 820. The single busbar 820 is positioned on a top surface of each of the plurality of switches 810. In other words, the single busbar 820 is positioned across the top surface of each of the plurality of switches 810. FIG. 8 also illustrates an embodiment 825. The embodiment 825 includes the PCB 805 having the first surface 810 and the plurality of switches 815 are arranged on the first surface 810. In the embodiment 825, the plurality of busbars 820 is a single busbar 820. The single busbar 820 is positioned on a top surface of each of the plurality of switches 810. In the embodiment 825, the single busbar 820 is connected to the first surface 810 via a busbar connecting portion 822. In some embodiments, the busbar connecting portion 822 is an extension of the single busbar 820 that connects the single busbar 820 to the first surface 810. For example, the busbar connecting portion 822 extends from the single busbar 820 and is soldered to the first surface 810.

As shown in FIG. 8, an embodiment 830 includes the plurality of switches 815 arranged on the first surface 810 of the PCB 805. The embodiment 830 includes the plurality of busbars 820 arranged on a respective top surface of the plurality of switches 815. In other words, each busbar of the plurality of busbars 820 is arranged on the top surface of a corresponding switch of the plurality of switches 815. FIG. 8 also illustrates an embodiment 835. The embodiment 835 includes the PCB 805 having the first surface 810 and the plurality of switches 815 are arranged on the first surface 810. In the embodiment 835, the plurality of busbars 820 is the single busbar 820. The single busbar 820 is positioned on a top surface of one or more switches of the plurality of switches 810. As shown in the embodiment 835, the single busbar 820 is connected to the first surface 810 via the busbar connecting portion 822.

FIG. 8 also illustrates an embodiment 840. The embodiment 840 includes the plurality of switches 815 arranged on the first surface 810 of the PCB 805. The embodiment 840 includes the plurality busbars 820 arranged on a respective top surface of the plurality of switches 815. In other words, each busbar of the plurality of busbars 820 is arranged on the top surface of a corresponding switch of the plurality of switches 815. Additionally, the embodiment 840 includes busbars of the plurality of busbars 820 that are directly connected to the first surface 810. In other words, the embodiment 840 includes some busbars of the plurality of busbars 820 that are directly connected to the first surface 810 that are not arranged on the top surface of a corresponding switch of the plurality of switches 815. FIG. 8 also illustrates an embodiment 845. The embodiment 845 includes the PCB 805 having the first surface 810 and the plurality of switches 815 are arranged on the first surface 810. In the embodiment 845, the plurality of busbars 820 is the single busbar 820. The single busbar 820 is positioned on a top surface of each of the plurality of switches 810. In the embodiment 845, the single busbar 820 is connected to the first surface 810 via a plurality of busbar connecting portions 822.

As shown in FIG. 8, an embodiment 850 includes the plurality of switches 815 arranged on the first surface 810 of the PCB 805. The embodiment 850 includes the plurality of busbars 820 directly connected to the first surface 810 without any of the plurality of busbars 820 arranged on the top surface of any of the plurality of switches 815. FIG. 8 also illustrates an embodiment 855. The embodiment 855 includes the plurality of switches 815 arranged on the first surface 810 of the PCB 805. The embodiment 855 includes the plurality of busbars 820 arranged on a respective top surface of the plurality of switches 815. In other words, each busbar of the plurality of busbars 820 is arranged on the top surface of a corresponding switch of the plurality of switches 815. In the embodiment 855, each busbar of the plurality of busbars 820 is connected to the first surface 810 via a corresponding busbar connecting portion 822 of the plurality of busbar connecting portions 822.

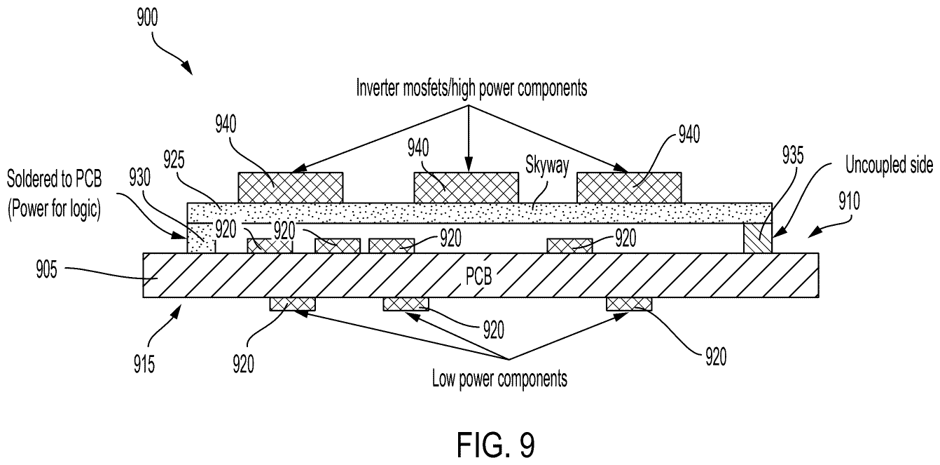

FIG. 9 illustrates an embodiment 900 of a printed circuit board (“PCB”) 905, with like parts to PCBs 400, 500, 600, and 805. The illustrated embodiment in FIG. 9 having like reference numbers in the range of 900 to 999, and the differences are explained below. The PCB 905 is electrically connected to the power source 110, the motor 300, and includes the controller 200. Additionally, the PCB 905 defines a first surface 910 and a second surface 915 opposing the first surface 910. The PCB 905 includes a plurality of electrical components 920 mounted on (e.g., via soldering) the first surface 910 and the second surface 915.

The PCB 905 includes a plurality of busbars 925 (e.g., one or more busbars 925) arranged as a skyway at a distance above the first surface 910 and providing a clearance between the first surface 910 and the plurality of busbars 925. The plurality of busbars 925 are connected to the first surface 910 at a busbar connecting portion 930. In some embodiments, the busbar connecting portion 930 is an extension of the plurality of busbars 925 that is soldered to the first surface 910. In some embodiments, the plurality of busbars 925 are not connected to the first surface 910 at an uncoupled side 935 such that the plurality of busbars 925 only connect to the first surface 910 at the busbar connecting portion 930.

The PCB 905 also includes a plurality of switches 940. The plurality of switches 940 are mounted to the plurality of busbars 925 away from the first surface 910. For example, the plurality of switches 940 are mounted on a first surface of the plurality of busbars 925 that is opposite the second surface, where the second surface faces the PCB 905. By mounting the plurality of switches 940 on the plurality of busbars 925 (e.g., mounting the plurality of switches 940 to the plurality of busbars 925 arranged as the skyway), a main power path from the power source 110 to the plurality of switches 940 is removed from the first surface 910. As shown in the embodiment 900, the main power path moves through the plurality of busbars 925 to the plurality of switches 940. In some embodiments, moving the main power path from the PCB 905 reduces a temperature of the PCB 905. In some embodiments, the material composition of each busbar of the plurality of busbars 925 is copper.

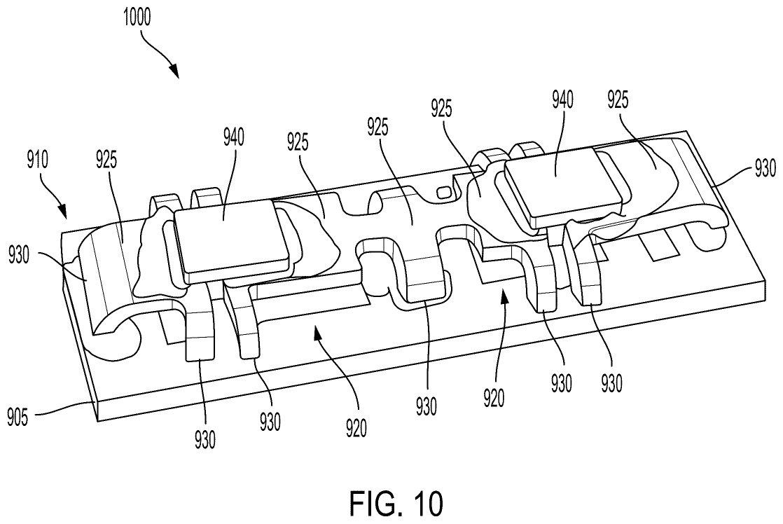

FIG. 10 illustrates an isometric view 1000 of the PCB 905 of FIG. 9. As shown in FIG. 10, the PCB 905 includes the first surface 910. Although not visible in the isometric view 1000, it should be understood that the PCB 905 includes the second surface 915 opposite the first surface 910. The PCB 905 includes the plurality of electrical components 920 mounted on the first surface 910. The PCB 905 also includes the plurality of busbars 925 arranged as the skyway at a distance above the first surface 910 and connected to the first surface 910 at the busbar connecting portion 930. As shown in the isometric view 1000, in some embodiments, the busbar connecting portion 930 is a plurality of busbar connecting portions 930. The PCB 905 includes the plurality of switches 940 mounted on the plurality of busbars 925 arranged as the skyway.

Thus, embodiments described herein provide, among other things, a power tool including a printed circuit board with busbars. Various features and advantages are set forth in the following claims.

What is claimed is:

1. A power tool comprising:
a motor;
a power source configured to supply power to the motor; and
a printed circuit board (“PCB”) electrically connected to the motor and the power source, the PCB including a switch and a busbar arranged on a surface of the PCB, the busbar electrically connecting the power source to the switch.

2. The power tool of claim 1, wherein the PCB includes a plurality of high-side switches and a plurality of low-side switches and wherein the switch is one of the plurality of high-side switches.

3. The power tool of claim 1, wherein the PCB includes a plurality of high-side switches and a plurality of low-side switches and wherein the switch is one of the plurality of low-side switches.

4. The power tool of claim 2, wherein the busbar is a positive busbar electrically connecting the power source to the plurality of high-side switches.

5. The power tool of claim 3, wherein the PCB includes a negative busbar electrically connecting the power source to the plurality of low-side switches.

6. The power tool of claim 1, wherein power is supplied to the motor from the power source by controlling the switch.

7. The power tool of claim 1, wherein the busbar is made of one selected from the group consisting of copper, brass, and aluminum.

8. The power tool of claim 1, wherein the surface is a first surface, the switch is a first switch arranged on the first surface, the first switch having a first top surface, and the busbar is a first busbar arranged on the first top surface of the first switch, the first busbar electrically connecting the power source to the first switch.

9. The power tool of claim 8, wherein the PCB further includes:
a second surface opposite the first surface;
a second switch arranged on the second surface, the second switch having a second top surface; and
a second busbar arranged on the second top surface of the second switch, the second busbar electrically connecting the power source to the second switch.

10. An electrical device comprising:
a power tool battery pack configured to supply power to a power input; and
a printed circuit board (“PCB”) including the power input and a power output, the PCB including a switch and a busbar arranged on a surface of the PCB, the busbar providing power from the power input through the switch to the power output.

11. The electrical device of claim 10, wherein the electrical device is one selected from the group consisting of a portable power source, a lighting device, and a power tool.

12. The electrical device of claim 10, wherein the busbar electrically connects the power input to the switch.

13. The electrical device of claim 10, wherein the busbar electrically connects the switch to the power output.

14. The electrical device of claim 10, wherein the electrical device includes a motor electrically connected to the power output, the electrical device supplies power to the motor by controlling the switch.

15. The electrical device of claim 10, wherein the power input is a connector interface, the connector interface is electrically connected to the power tool battery pack and configured to receive power from the power tool battery pack.

16. A power tool comprising:
a motor;
a power source configured to supply power to the motor; and
a printed circuit board (“PCB”) electrically connected to the motor and the power source, the PCB including a motor drive circuit having a plurality of high-side switches, a plurality of low-side switches, and a first busbar arranged on a surface of the PCB, the first busbar electrically connecting a positive terminal of the power source to each of the plurality of high-side switches.

17. The power tool of claim 16, wherein the motor drive circuit includes a second busbar arranged on the surface of the PCB, the second busbar electrically connecting a negative terminal of the power source to each of the plurality of low-side switches.

18. The power tool of claim 17, wherein the motor drive circuit includes a plurality of third busbars arranged on the surface of the PCB, the plurality of third busbars electrically connecting the plurality of high-side switches to the motor.

19. The power tool of claim 18, wherein the plurality of third busbars electrically connect the plurality of low-side switches to the motor.

20. The power tool of claim 16, wherein power is supplied to the motor from the power source by controlling the plurality of high-side switches and the plurality of low-side switches.
